(19) United States
(12) Patent Application Publication
(10) Pub. No.: US 2026/0029491 A1
(43) Pub. Date: Jan. 29, 2026

(54) CASCADE MAGNETIC SENSOR CIRCUIT AND A LINEAR MAGNETIC SENSOR DEVICE COMPRISING THE CASCADE MAGNETIC SENSOR CIRCUIT

(71) Applicant: Allegro MicroSystems, LLC, Manchester, NH (US)

(72) Inventors: Santiago Serrano-Guisan, San Jose, CA (US); Anuraag Mohan, Fremont, CA (US)

(73) Assignee: Allegro MicroSystems, LLC, Manchester, NH (US)

(21) Appl. No.: 18/997,642

(22) PCT Filed: Jul. 21, 2023
(86) PCT No.: PCT/IB2023/057466

§ 371 Date: Jan. 22, 2025

(30) Foreign Application Priority Data
Jul. 22, 2022 (EP) 22315165.5

(51) Int. Cl. G01R 33/00; G01R 33/09

(52) U.S. Cl. CPC G01R 33/0029; G01R 33/0094; G01R 33/098

(57) ABSTRACT

The present disclosure concerns magnetic sensor device (10) for sensing an external magnetic filed vector (H) comprising a cascade magnetic sensor circuit (100) comprises N magnetic sensors (2ₙ), wherein N equal to or greater than 2, wherein said N magnetic sensors (2ₙ) comprises a first magnetic sensor (2₁) and at least another magnetic sensor (2ₙ) electrically connected in cascade with each other. The first magnetic sensor (2₁) is configured to generate a first output voltage (Vₒᵤₜ₁) dependent on an external magnetic field vector (H) when inputted with an input bias voltage (V_{dd}). The output voltage of the n^{th} magnetic sensor is used as input bias voltage of the next (n+1) magnetic sensor. The magnetic sensor device (10) further comprises at least one reference magnetic field sensor (2_{Ref}). The corrected output voltage has improved linearity compared to the reference output voltage.

### TECHNICAL DOMAIN

The present disclosure concerns a cascade magnetic sensor circuit configured to generate a non-linear cascade output voltage. The present disclosure further concerns a magnetic sensor device comprising the cascade magnetic sensor circuit.

### RELATED ART

Linear magnetic sensors have many consumer, industrial and automotive applications. Current sensing, positioning, proximity detection, biometric sensing are some examples. Sensor technologies using Magnetic Tunnel Junctions (MTJs) based on Tunnel Magneto-Resistance (TMR) effect excel among rival technologies based on Anisotropic Magneto-Resistance (AMR) effect, Giant Magneto-Resistance (GMR) effect and Hall effect, thanks to their higher sensitivity and signal-to-noise ratio (SNR), lower temperature dependence, better long-term stability, and generally smaller die size.

Commonly, such sensors provide an output voltage Vₒᵤₜ that is roughly proportional to external applied magnetic field H. A typical response of a magnetic sensor inputted by a bias voltage V_{dd} and under an external magnetic field H can be approximated by equation 1a:

$${V}_{out} = [ {a}_{0} + {a}_{1} \cdot H + {\sum }_{j = 1}^{N} {a}_{j} \cdot {H}^{j} ] \cdot {V}_{dd} , \qquad Eq . 1 a$$

where a₀ is the sensor offset, a₁ is a linear coefficient (or Sensitivity) and aⱼ are the high order components, respectively and V_{dd} is the input bias voltage. Usually, a₁>>aⱼ, being each high order coefficient much larger than the next one. This implies that the larger the magnetic field is, the larger is the deviation of Vₒᵤₜ from a perfect linear response.

FIG. 1 shows a magnetic sensor 2 comprising four magnetic sensing elements 20 arranged in a full-bridge circuit, such as a Wheatstone bridge circuit. The magnetic sensing element 20 can comprise a magnetoresistive element, such as a magnetic tunnel junction. The differential output voltage Vₒᵤₜ (Vₒᵤₜ=Vₒᵤₜ₊−Vₒᵤₜ₋) response under an external magnetic field vector H can be approximated to equation 1 b:

$${V}_{out} ∼ [ {a}_{0} + {a}_{1} \cdot H - {a}_{3} \cdot {H}^{3} ] \cdot {V}_{dd} \qquad Eq . 1 b$$

where a₁, and a₃ are the linear and 3^{rd} order coefficients. Eq. 1 can be rewritten as:

$${V}_{out} ∼ {v}_{s} ( H ) \cdot {V}_{dd} ; \qquad Eq . 2 a$$

where vₛ expresses the intrinsic dependence of the magnetic sensor when submitted to an external magnetic field (for example, vₛ does not depend on V_{dd}) (i.e., the normalized output voltage of the sensor):

$${v}_{s} ( H ) = [ {a}_{0} + {a}_{1} \cdot H - {a}_{3} \cdot {H}^{3} ] . \qquad Eq . 2 b$$

The linearity of such magnetic sensors can generally be improved by the development of a magnetoresistive element, such as a magnetic tunnel junction, that ensures a linear Vₒᵤₜ response and larger working magnetic field ranges. However, the improvement in linearity of the magnetoresistive element usually comes at the expense of a reduction of sensor sensitivity and magnetic field resolution.

Improving the linearity of the magnetic sensor without reduction of sensitivity has been proposed relying on the implementation of an integrated circuit (IC) configured to correct the non-linearities and obtain a high linear corrected output voltage V_{corr}. International patent application number WO2021IB60743 by the present applicant describes a continuous compensation of next high order harmonic component of Vₒᵤₜ by the implementation of an IC configured to generate a high non-linear voltage that continuously compensates the next high order harmonic component of Vₒᵤₜ. Usually, the more complex is the IC the more linear is the corrected output voltage V_{corr}, but at the expense of being more limited to work at high frequencies.

Other solutions can include using a lookup table or calculating a correction polynomial. Such solutions require the use of ADCs, DACs, memory, and a microcontroller and involve full digital reconstruction of V_{corr}, usually with high power consumption, lower speed, and large die area.

### SUMMARY

The present disclosure concerns a magnetic sensor device for sensing an external magnetic field vector comprising a cascade magnetic sensor circuit comprising N magnetic sensors, wherein N equal to or greater than 2, wherein each magnetic sensor outputs an output voltage Vₒᵤₜₙ, the magnetic sensors being electrically connected in cascade with each other, wherein the output voltage Vₒᵤₜₙ of the n^{th} magnetic sensor of the cascade magnetic sensor circuit supplies the input bias voltage V_{dd_n+1} of the next magnetic sensor (n+1)^{th}:

$${V}_{outn} = {V}_{dd \_ ( n + 1 )} ;$$

wherein the output voltage of the n^{th} magnetic sensor Vₒᵤₜₙ is proportional to the input bias voltage V_{dd_n} inputted to the n^{th} magnetic sensor and to a normalized output voltage v_{s_n} of the n^{th} magnetic sensor depending on an external magnetic field vector H:

$${V}_{outn} = {v}_{s \_ n} ( H ) \cdot {V}_{dd \_ n} ;$$

wherein the normalized output voltage v_{s_n} expresses the intrinsic dependence of the magnetic sensor when submitted to the external magnetic field vector. The magnetic sensor device further comprises at least one reference magnetic field sensor wherein a corrected output voltage V_{corr} of the magnetic sensor device is determined by:

$${V}_{corr} = a \cdot {V}_{outRef} + b \cdot {V}_{outCascade}$$

where a and b are correction parameters independent of the external magnetic field vector, V_{outRef} is a reference output voltage generated by at least one reference magnetic sensor, the corrected output voltage having improved linearity compared to the reference output voltage, and V_{outCascade} is the cascade output voltage of the cascade magnetic sensing circuit.

In an embodiment, the cascade sensor circuit is configured to generate a cascade output voltage:

$${V}_{outCascade} = {V}_{dd} \cdot {\prod }_{n = 1}^{N} {v}_{s \_ n} ,$$

where V_{outCascade} is the cascade output voltage and V_{dd} is the bias voltage applied to the first magnetic sensor of the cascade magnetic sensor circuit.

In another embodiment, the cascade sensor circuit is configured to generate a cascade output voltage determined by:

$${V}_{outCascade} = {\sum }_{n = 1}^{N} {α}_{n} \cdot {V}_{outn} ,$$

where the Vₒᵤₜₙ is the voltage output of the n^{th} magnetic sensor and αₙ coefficient is independent of the external magnetic field vector and at least one of the αₙ coefficients is non zero.

The cascade sensor circuit can be configured to correct high order components of a first output voltage Vₒᵤₜ₁ of the first magnetic sensor of the N magnetic sensors, and/or generate any desired polynomial output voltage response.

The coefficients a and b may depend on the configuration of the cascade magnetic sensor circuit, and this may depend on the magnetic sensor's coefficients (a₁, . . . , a_{N}) of all N magnetic sensors involved in such a magnetic sensor device.

The magnetic sensor device outputs a corrected output voltage having improved linearity with magnetic field amplitude and/or magnetic field orientation compared to the reference output voltage.

The magnetic sensor device can provide a linear signal without relying on CMOS processing, analog IC development, implementation and/or IC trimming. Instead, the cascade sensor compensates the non-linear coefficients of the output voltage of the magnetic sensor device, ensuring a linear magnetic sensor device with higher bandwidth operation.

The magnetic sensor device can correct the output voltage for higher order components, such as 5th order and beyond to increase the magnetic field range operation or improve linearity. The magnetic sensor device has an improved linearity as a function of temperature and is compatible with a correction of the temperature coefficient of sensitivity.

The cascade sensor circuit can be configured to linearize and angular magnetic sensor therefore the magnetic sensor device has an improved linearity with respect to the orientation of the magnetic field, improving the working angular range of angular magnetic sensors for auto-focus (AF) applications.

### SHORT DESCRIPTION OF THE DRAWINGS

Exemplar embodiments of the invention are disclosed in the description and illustrated by the drawings in which:

FIG. 1 illustrates a magnetic sensor comprising four magnetic sensing elements arranged in a full bridge circuit;

FIG. 2 shows a cascade sensor circuit, according to an embodiment;

FIG. 3 shows a cascade sensor device comprising three magnetic sensors, according to an embodiment;

FIG. 4 shows a general configuration of the cascade magnetic sensor circuit comprising N magnetic sensors, according to an embodiment;

FIG. 5 illustrates a magnetic sensor device for sensing an external magnetic field vector and comprises the cascade magnetic sensor circuit, according to an embodiment;

FIG. 6 shows a generic representation of the magnetic sensor device 10, according to an embodiment;

FIG. 7 illustrates an example of the magnetic sensor device of FIG. 6;

FIG. 8 shows the cascade output voltage of the cascade sensing circuit as a function of the reference output voltage for the magnetic sensor device of FIG. 5;

FIG. 9a shows the reference output voltage V_{outRef} of a reference magnetic sensor as well as the corrected output voltage V_{corr} of the magnetic sensor device of FIG. 5 as a function of the applied magnetic field, when submitted to a bias voltage of 1V;

FIG. 9b show the linearity error of both the reference output voltage V_{outRef} of the reference magnetic sensor as well as the corrected output voltage V_{corr} of the magnetic sensor device of FIG. 5

FIG. 10a shows the dependence of the linearity error of the corrected output voltage of the magnetic sensor device of FIG. 7 as a function of the bias voltage of the cascade sensing circuit V₀ when the bias voltage of the reference magnetic sensor V_{dd} equals 1V;

FIG. 10b shows the experimentally determined bias voltage of the cascade sensing circuit V₀ necessary to obtain the lowest linearity error of the corrected output voltage of the magnetic sensor device of FIG. 7 when the reference magnetic sensor is biased by 1V;

FIGS. 11a and 11b show the sensitivity (FIG. 11a) and linearity error (FIG. 11b) of the reference output voltage of the reference magnetic sensor (V_{outRef}) and the corrected output voltage of the magnetic sensor device of FIG. 7 as a function of temperature;

FIGS. 12a report the third order coefficient as a function of temperature;

FIG. 12b shows a variation of the bias voltage of the cascade sensing circuit V₀ of the magnetic sensor device of FIG. 7 such that the linearity error is smaller than 0.08% at all temperature range;

FIG. 13 illustrates a 2D magnetic sensor device, according to an embodiment;

FIG. 14 shows the corrected output voltage (FIG. 14a), the reference output voltage (FIG. 14b) and the linearity error (FIG. 14c) with respect to the magnetic field orientation of the 2D magnetic sensor device of FIG. 13;

FIG. 15 illustrates a 2D magnetic sensor device, according to another embodiment;

FIG. 16 illustrates a cascade sensor circuit for generating a polynomial output voltage response, according to another embodiment.

### EXAMPLES OF EMBODIMENTS

FIG. 2 illustrates a cascade magnetic sensor circuit 100 according to an embodiment. The cascade magnetic sensor circuit 100 is shown comprising two magnetic sensors (2ₙ₌₁, 2ₙ₌₂ or 2₁, 2₂) electrically connected in cascade with each other.

It should be understood that the cascade magnetic sensor circuit 100 can comprise more than two magnetic sensors. More generally, the cascade magnetic sensor circuit 100 can comprise N magnetic sensors 2n, wherein N equal to or greater than 2, where the magnetic sensors 2n are electrically connected in cascade with each other. The output voltage Vₒᵤₜ of the n^{th} magnetic sensor of the cascade magnetic sensor circuit 2ₙ (with n≤N) is proportional to the input bias voltage V_{dd_n} of the n^{th} magnetic sensor 2ₙ and to the normalized output voltage v_{s_n} of the magnetic sensor 2ₙ depending on the external magnetic field vector H, as defined by equation 3:

$${V}_{outn} = {v}_{s \_ n} ( H ) \cdot {V}_{dd \_ n} , \qquad Eq . 3$$

where v_{s_n} can be defined by equation 2b.

The output voltage Vₒᵤₜₙ of the n^{th} magnetic sensor 2n supplies the input bias voltage V_{dd_n+1} of the next magnetic sensor 2ₙ₊₁. The cascade sensor circuit 100 generates therefore an output voltage V_{outCascade}, as defined by equation 4:

$${V}_{outCascade} = {V}_{dd} \cdot {\prod }_{n = 1}^{N} {v}_{s \_ n} , \qquad Eq . 4 a$$

where V_{dd} is the input bias voltage of the first magnetic sensor of the cascade sensor circuit.

In another embodiment, an amplification stage (gₙ) at the output of at least 1 of the N magnetic sensors of the cascade circuit is used. The cascade sensor circuit generates therefore an output voltage (V_{outCascade}):

$${V}_{outCascade} = {V}_{dd} \cdot {\prod }_{n = 1}^{N} {g}_{n} \cdot {v}_{s \_ n} ( H ) , \qquad Eq . 4 b$$

where V_{dd} is the input bias voltage of the first magnetic sensor of the cascade sensor circuit.

In reference with FIG. 2, the cascade magnetic sensor circuit 100 comprises two magnetic sensor 2ₙ, including a first magnetic sensor 2₁, the two magnetic sensor 2ₙ are electrically connected in cascade. The first magnetic sensor 2₁ is configured to generate a first output voltage V_{out_1} dependent on the external magnetic field vector H as described by equation 3.

The normalized output voltage v_{s_n} (H) of the second magnetic sensor 2ₙ can have a substantially identical dependence on the external magnetic field vector H as the normalized output voltage vₛ(H) of the first magnetic sensor 2₁. Therefore, the output voltage Vₒᵤₜₙ of the second magnetic sensor 2ₙ is proportional to a degree n (here n=2) with respect to the first output voltage Vₒᵤₜ₁ of the first magnetic sensor 2₁. In this embodiment, the cascade magnetic sensor circuit 100 outputs a cascade output voltage V_{outCascade} that corresponds to the output voltage Vₒᵤₜₙ of the second magnetic sensor 2ₙ.

The first magnetic sensor 2₁ and the second magnetic sensor 2ₙ can comprise four magnetic sensing elements 20 arranged in a full-bridge circuit, such as a Wheatstone bridge circuit. The magnetic sensing element can comprise a magnetoresistive element, such as a magnetic tunnel junction. The first magnetic sensor 2₁ is electrically connected in cascade with the second magnetic sensor 2ₙ such that the first differential output voltages Vₒᵤₜ₁₊ and Vₒᵤₜ₁₋ of the first magnetic sensor 2₁ (nodes C and D) are respectively connected to the bias inputs (nodes A and B) of the second magnetic sensor 2ₙ.

The first output voltage Vₒᵤₜ₁ is a differential output voltage that is equal to the difference between Vₒᵤₜ₁₊ and Vₒᵤₜ₁₋ of the full-bridge circuit. The first output voltage Vₒᵤₜ₁ follows equations 2a₁2b and 3. When subjected to an external applied magnetic field H, the first magnetic sensor 2₁ produces the first output voltage Vₒᵤₜ₁ between points C and D and can be expressed by equation 4b:

$${V}_{out \_ 1} = {V}_{out 1 +} - {V}_{out 1 -} = {V}_{dd} \cdot {v}_{s \_ 1} ( H ) , \qquad Eq . 4 b$$

where V_{dd} is the bias voltage applied to the first magnetic sensor 2₁ and v_{s_1} (H) is the normalized output voltage of the first magnetic sensor 2₁ (described by Eq. 2b).

The second output voltage Vₒᵤₜₙ, where n=2, of the second magnetic sensor 2ₙ can be expressed by equation 5a:

$${V}_{out 2} = {V}_{out 2 +} - {V}_{out 2 -} = {V}_{dd \_ 2} \cdot {v}_{s \_ 2} ( H ) , \qquad Eq . 5 a$$

where V_{dd_2} and v_{s_2}(H) are the input bias voltage and the normalized output voltage of the second magnetic sensor 2₂ respectively. However, in this cascade configuration, the output voltage Vₒᵤₜ₁ of the first magnetic sensor 2₁ is used as input bias voltage of the second magnetic sensor 2ₙ (V_{dd_2}). Therefore:

$${V}_{out 2} = {V}_{out 1} \cdot {v}_{s 2} ( H ) = {V}_{dd} \cdot {v}_{s \_ 1} ( H ) \cdot {v}_{s \_ 2} ( H ) . \qquad Eq . 5 b$$

If the second magnetic sensor 2₂ is configured to have a similar magnetic field vector dependence than the one of the first magnetic sensor 2₁ (v_{s_2}=v_{s_1}), then:

$${V}_{out 2} = {V}_{dd} \cdot {v}_{s \_ 1}^{2} ( H ) ∼ {V}_{dd} \cdot {[ {a}_{0} + {a}_{1} \cdot H - {a}_{3} \cdot {H}^{3} ]}^{2} . \qquad Eq . 6 a$$

$$or :$$

$${V}_{out 2} = {V}_{dd} \cdot ( \frac{{V}_{out 1}^{2}}{{V}_{dd}^{2}} ) = {V}_{out 1}^{2} / {V}_{dd} . \qquad Eq . 6 b$$

As equation 6b shows, the differential output voltage Vₒᵤₜ₂ of the second magnetic sensor 2₂ is quadratic with respect to the first output voltage Vₒᵤₜ₁ of the first magnetic sensor 2₁ in case that both magnetic sensors have a similar magnetic field dependence.

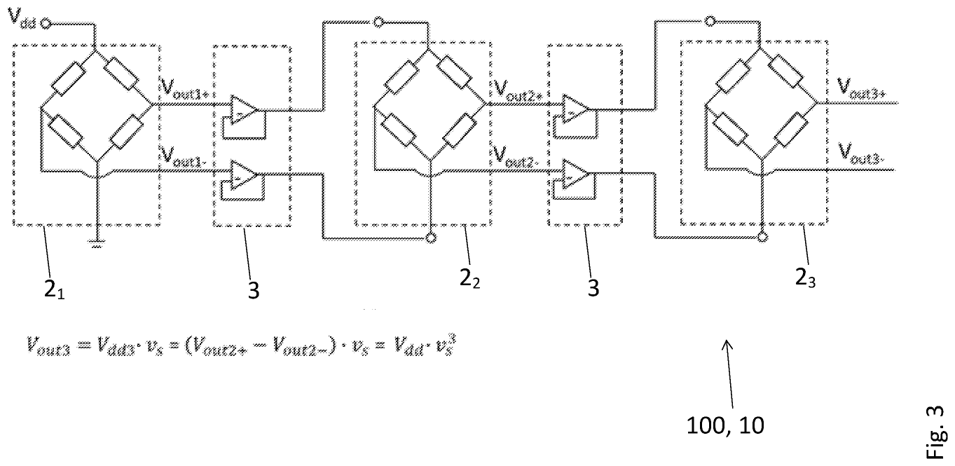

FIG. 3 shows the cascade sensor device 100 comprising three magnetic sensors 2ₙ (N=3), in particular a first magnetic sensor 2₁ and two other magnetic sensors 2₂ and 2₃. The three magnetic sensors are electrically connected in cascade with each other. The differential output voltages Vₒᵤₜₙ₊ and Vₒᵤₜₙ₋ of the n^{th} magnetic sensor 2ₙ can be respectively connected to the bias input of the following magnetic sensor (n+1) 2ₙ₊₁. In this configuration, output voltage Vₒᵤₜ₃ of the third magnetic sensor 2₃ can be expressed by equation 7:

$${V}_{out 3} = {V}_{out 2} \cdot {v}_{s \_ 3} ( H ) = {V}_{out 1} \cdot {v}_{s \_ 2} ( H ) \cdot {v}_{s 3} ( H ) = {V}_{dd} \cdot {v}_{s \_ 11} ( H ) \cdot {v}_{s \_ 2} ( H ) \cdot {v}_{s \_ 3} ( H ) . \qquad Eq . 7$$

The three magnetic sensors 2ₙ can have a substantially identical dependence on the external magnetic field vector H (v_{s_1}(H)=v_{s_2}(H)=v_{s_3}(H)). For this configuration, the output voltage Vₒᵤₜ₃ of the third magnetic sensor can be expressed by equation 8a:

$${V}_{out 3} = {V}_{dd} \cdot {v}_{s \_ 11}^{3} ( H ) ∼ {V}_{dd} \cdot {[ {a}_{0} + {a}_{1} \cdot H - {a}_{3} \cdot {H}^{3} ]}^{3} . \qquad Eq . 8 a$$

Equation 8a can also be rewritten as:

$${V}_{out 3} = {V}_{dd} \cdot ( \frac{{V}_{out 1}^{3}}{{V}_{dd}^{3}} ) = {V}_{out 1}^{3} / {V}_{dd}^{2} . \qquad Eq . 8 b$$

As shown in Eq. 8b, the output voltage Vₒᵤₜ₃ of the third magnetic sensor 2₃ is cubic with respect to the first output voltage Vₒᵤₜ₁ in case that the three magnetic sensors have a similar magnetic field dependence.

Therefore, for this configuration (FIG. 3) the cascade magnetic sensor circuit 100 outputs a cascade output voltage V_{outCascade} that corresponds to the output voltage of the third magnetic sensor 2₃.

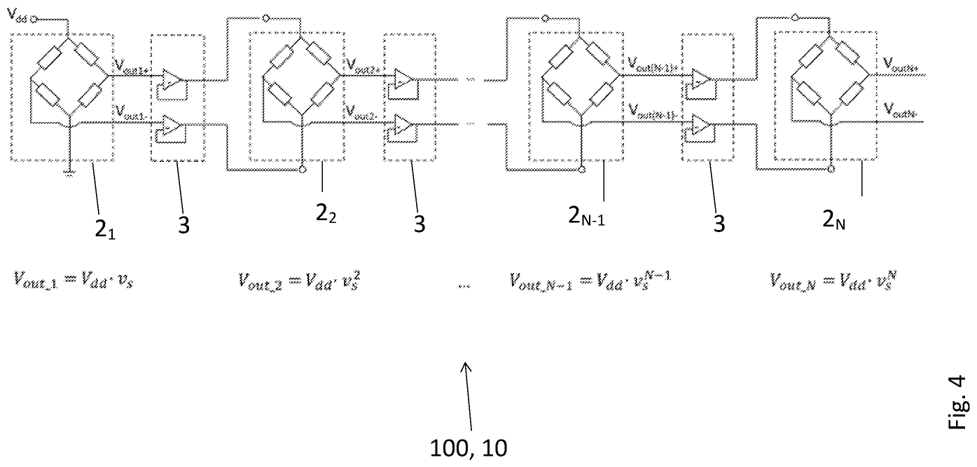

FIG. 4 shows a more general configuration of the cascade magnetic sensor circuit 100 comprising a plurality of (here, more than three) magnetic sensors 2ₙ electrically connected in cascade with each other. Here, the cascade magnetic sensor circuit 100 comprises N magnetic sensors 2ₙ, where N>3.

In this configuration, the cascade magnetic sensor circuit 100 outputs a cascade output voltage V_{outCascade} that corresponds to the output voltage V_{outN} of the N^{th} magnetic sensor 2_{N} and is described by equation 4.

In the case that all the N magnetic sensors 2ₙ of the cascade sensing circuit 100 have a substantially identical magnetic field vector dependence (v_{s_1} (H)=v_{s_2}(H)= . . . =v_{s_N}(H)), then:

$${V}_{outCascade} = {V}_{dd} \cdot {v}_{s \_ 11}^{N} ( H ) ∼ {V}_{dd} \cdot {[ {a}_{0} + {a}_{1} \cdot H - {a}_{3} \cdot {H}^{3} ]}^{N} . \qquad Eq . 9 a$$

Equation 9a can also be rewritten as:

$${V}_{outCascade} = {V}_{dd} \cdot ( \frac{{V}_{out 1}^{N}}{{V}_{dd}^{N}} ) = {V}_{out 1}^{N} / {V}_{dd}^{N - 1} \qquad Eq . 9 b$$

In this configuration, each n^{th} stage of the cascade sensing circuit 100 generates an output voltage Vₒᵤₜₙ that is proportional to the n^{th} power of the first output voltage Vₒᵤₜ₁ of the first magnetic sensor 2₁ of the cascade sensing circuit 100.

Referring again to FIG. 2, the cascade sensor circuit 100 comprises an amplifier buffer 3 electrically connected between the differential output voltages Vₒᵤₜ₁₊ and Vₒᵤₜ₁₋ (points C and D) of the first magnetic sensor 2₁ and the bias inputs (points A and B) of the magnetic sensor 2ₙ. Referring to FIGS. 3 and 4, the cascade sensor circuit 100 can further comprise an amplifier buffer 3 between the n-1 output voltage V_{outn_1} of the n-1 magnetic sensor 2ₙ_, and the input of the n magnetic sensor 2ₙ. The amplifier buffer 3 prevents the input impedance of a magnetic sensor 2ₙ from loading the output impedance of the previous magnetic sensor 2_{n_1}, which would cause undesirable loss of signal transfer.

Similar to the cascade magnetic sensor circuit 100 shown in FIGS. 2 and 3, the magnetic sensors 2ₙ of the cascade magnetic sensor circuit 100 of FIG. 4 can comprise four magnetic sensing elements 20 arranged in a full-bridge circuit, such as a Wheatstone bridge circuit. The magnetic sensing element 20 can comprise a magnetoresistive element, such as a magnetic tunnel junction. For example, the magnetic sensing element 20 can comprise a magnetic tunnel junction comprising a reference layer having a reference magnetization and a sense layer having a sense magnetization that can be oriented relative to the reference magnetization, according to the orientation of the external magnetic field H.

The presented cascade magnetic sensor circuit 100 can be configured to improve the linearity of a magnetic sensor device for sensing the external magnetic field vector H.

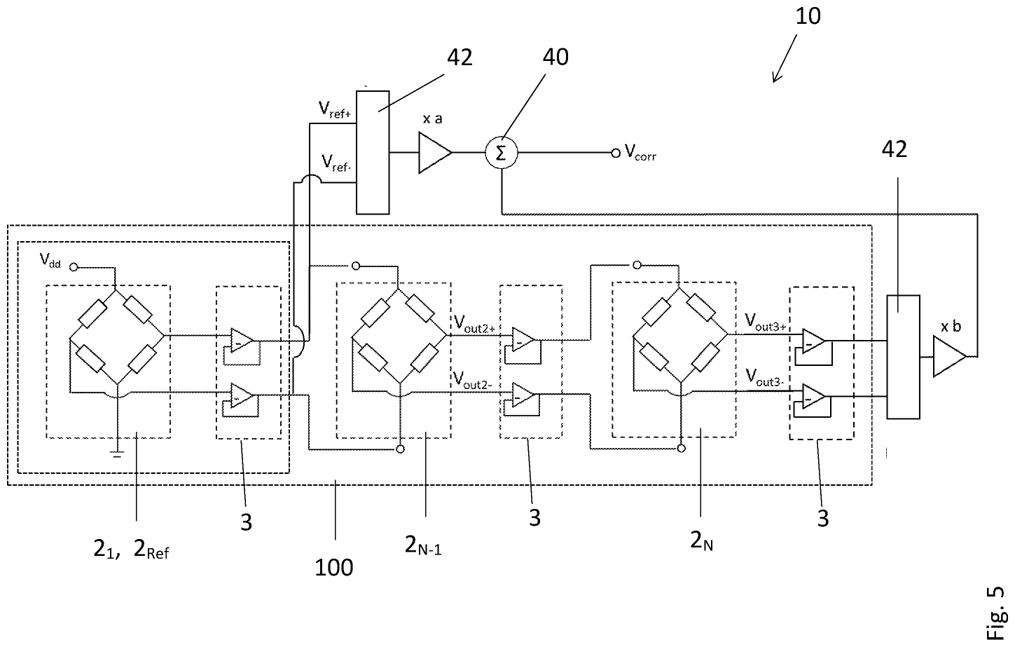

In an embodiment illustrated in FIG. 5, a magnetic sensor device for sensing an external magnetic field vector H comprises the cascade magnetic sensor circuit 100 including three magnetic sensors 2ₙ (N=3) connected in cascade. The output voltage Vₒᵤₜ₃ of the third magnetic sensor 2₃ can be used to compensate the non-linearity of the output voltage Vₒᵤₜ₁ of the first magnetic sensor 2₁. The output voltage Vₒᵤₜ, (differential output voltages Vₒᵤₜ₁₊ and Vₒᵤₜ₁₋) of the first magnetic sensors 2₁ is summed to the output voltage Vₒᵤₜ₃ (differential output voltages Vₒᵤₜ₃+ and Vₒᵤₜ₃₋) of the third magnetic sensor 2₃ by a summing circuit 40. Each of the output voltages Vₒᵤₜ₁ and Vₒᵤₜ₃ can be electrically connected to a differential amplifier 42. In the case the three magnetic sensors 2n have a substantially identical dependence on the external magnetic field vector H, the corrected output voltage V_{corr} of the magnetic sensor device 10 shown in FIG. 5 can be determined by equation 10:

$${V}_{corr} = a \cdot {V}_{out 1} + b \cdot {V}_{out 3} , \qquad Eq . 10$$

where a and b are correction parameters independent of the external magnetic field vector H. By adjusting the values of a and b, the corrected output voltage V_{corr} of the magnetic sensor device 10 shows an improved linearity compared to the first output voltage Vₒᵤₜ₁ of the first magnetic sensor 2₁.

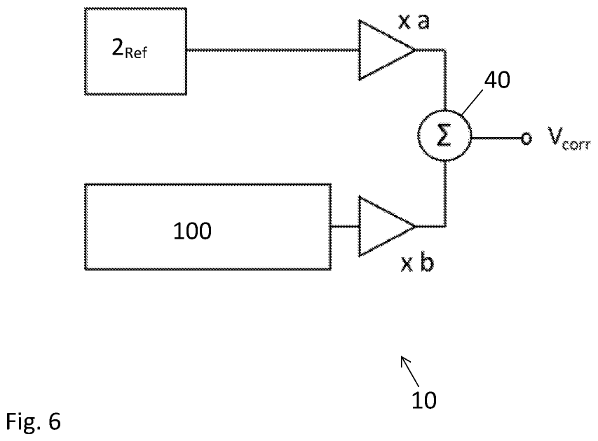

In one aspect, the cascade magnetic sensor circuit 100 can further comprise an amplifier buffer at the output of each magnetic sensor of the cascade magnetic circuit 100. FIG. 6 shows a generic representation of the magnetic sensor device 10, according to an embodiment. The magnetic sensor device 10 comprises a cascade sensing circuit 100 and a reference magnetic sensor 2_{Ref} configured to generate a reference output voltage V_{outRef} dependent on the external magnetic field vector H such that the corrected output voltage V_{corr} of the magnetic sensor device 10 is determined by:

$${V}_{corr} = a \cdot {V}_{outRef} + b \cdot {V}_{outCascade} . \qquad Eq . 11$$

Note that for such a configuration, the reference magnetic sensor is biased by a voltage V_{dd} and the cascade sensing circuit 100 is biased by a voltage V₀. Moreover, the correction parameters a and b can depend on the first and third order coefficient (a₁ and a₃) of the reference magnetic sensor. In FIG. 6, the magnetic sensor device 10 is represented with an amplifier xa after the reference magnetic sensor 2_{Ref}, and an amplifier xb after the cascade sensing circuit 100.

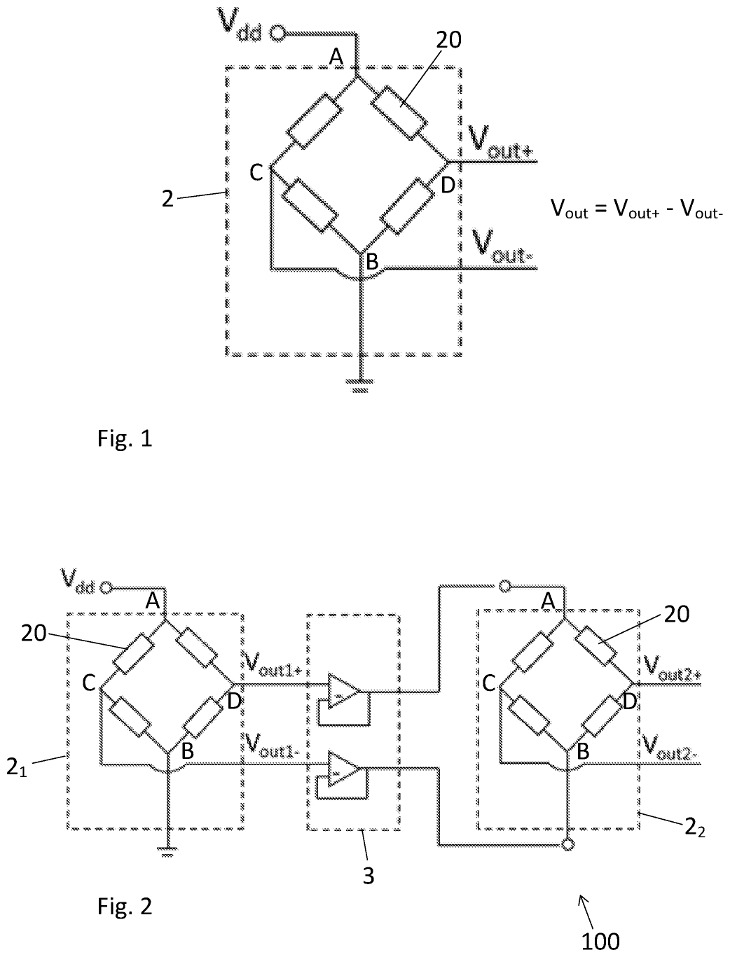

In the configurations of FIGS. 1 to 5, the first magnetic sensor 2₁ can play the role of a reference magnetic sensor 2_{Ref} and the reference magnetic sensor and the cascade sensing circuit are biased by the same bias voltage (V₀=V_{dd}). In the configuration of FIG. 6, the reference magnetic sensor 2_{Ref} is arranged separately from the cascade sensing circuit 100. The reference output voltage V_{outRef} of the reference magnetic sensors 2_{Ref} is summed to the cascade output voltage V_{outCascade} of the cascade sensing circuit 100 by a summing circuit 40.

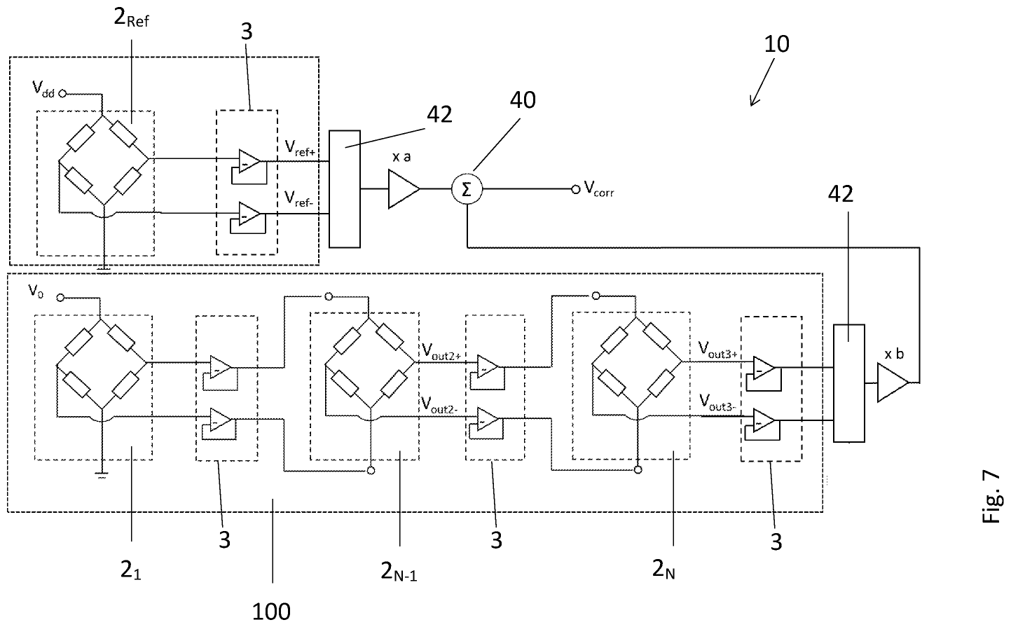

FIG. 7 illustrates an example of the magnetic sensor device 10 of FIG. 6, where the cascade sensing circuit 100 comprises three magnetic sensors 2n. Each of the three magnetic sensors 2n and the reference magnetic sensor 2_{Ref} comprises four magnetic sensing elements 20 arranged in a full-bridge circuit, such as a Wheatstone bridge circuit. The magnetic sensing element 20 can comprise a magnetoresistive element, such as a magnetic tunnel junction. The reference magnetic sensor 2_{Ref} can be inputted by an input bias voltage V_{dd} such that the reference magnetic sensor 2_{Ref} generates the first reference output voltage V_{outRef} dependent on the external magnetic field vector H. Because the response of the cascade sensing circuit 100 is proportional to the input bias voltage of the first magnetic sensor 2₁ of the cascade sensing circuit, the input bias voltage of the first magnetic sensor 2₁ of the cascade sensing circuit 100 can be referred to as the bias voltage of the cascade sensing circuit. The cascade sensing circuit 100 can be biased with an input bias voltage V₀ such that the cascade sensing circuit 100 generates the cascade output voltage V_{outCascade}. Similar to the cascade sensing circuit 100 shown in FIG. 5, the cascade output voltage V_{outCascade} is generated by the output voltage Vₒᵤₜ₃ of the third (or last) magnetic sensor 2₃ of the cascade sensing circuit 100. The reference output voltage V_{outRef} of the reference magnetic sensor 2_{Ref} is electrically connected to cascade output voltage V_{outCascade} via a summing circuit 40. Each of the output voltages, the cascade output voltage V_{outCascade} of the cascade sensing circuit 100, as well as the reference output voltage V_{outRef} of the reference magnetic sensor 2_{Ref}, can be electrically connected to a differential amplifier 42.

In one aspect, the magnetic sensor device 10 can further comprise an amplifier buffer 3 at the output of each magnetic sensor of the magnetic sensor device.

In the case the magnetic sensing element 20 comprises a magnetic tunnel junction element and the reference magnetic sensor 2_{Ref} is biased at V_{dd}, the reference output voltage V_{outRef} can be expressed by equation 12:

$${V}_{outRef} = {V}_{d d} \cdot {v}_{s \_ Ref} ( H ) ∼ {V}_{d d} \cdot [ {a}_{0} + {a}_{1} \cdot H - {a}_{3} \cdot {H}^{3} ] , \qquad Eq . 12$$

where v_{s_Ref} (H) is the normalized output voltage of the reference magnetic sensor

In the case where the magnetic sensors 2ₙ of the magnetic sensor circuit 100 have a similar magnetic field vector dependence than the reference magnetic sensor the cascade output voltage V_{outCascade} can be expressed by equation 13:

$${V}_{outCascade} = {V}_{0} \cdot {{v}_{s \_ Ref} ( H )}^{3} ∼ {V}_{0} \cdot {[ {a}_{0} + {a}_{1} \cdot H - {a}_{3} \cdot {H}^{3} ]}^{3} . \qquad Eq . 13$$

By summing the reference output voltage V_{outRef} to the cascade output voltage V_{outCascade}, a corrected output voltage V_{corr} is obtained:

$${V}_{corr} = {V}_{outRef} + {V}_{outCascade} = {V}_{d d} \cdot [ {v}_{s \_ Ref} ( H ) + \frac{{V}_{0}}{{V}_{d d}} \cdot {{v}_{s \_ Ref} ( H )}^{3} ] . \qquad Eq . 14$$

Note that in this particular case, coefficients a and b from Eq.11 are a=b=1.

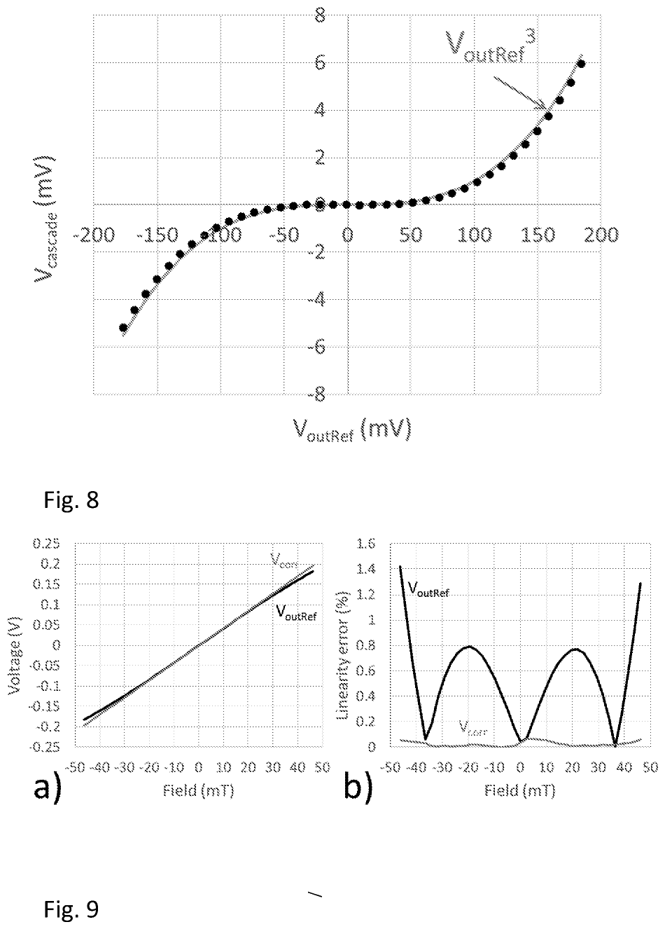

FIG. 8 shows the cascade output voltage V_{outCascade} of the cascade sensing circuit 100 as a function of the reference output voltage V_{outRef} for the magnetic sensor device 10 of FIG. 5, when the input bias voltage V_{dd} applied at the reference magnetic sensor 2_{Ref} and the input bias voltage V₀ applied at the cascade sensing circuit 100 are V_{dd}=V₀=1V. The output voltage generated by the cascade sensing circuit 100 V_{outCascade} (points) follows closely the cube of the reference output voltage V_{outRef} (continuous grey line) as expected by Eq. 8b. FIG. 8 shows therefore that the cascade sensing circuit 100 can provide a non-linear response that can be used to compensate the non-linearity of other voltage signals.

FIG. 9a shows the reference output voltage V_{outRef} (black curve) of the reference magnetic sensor 2_{Ref} as a function of the applied magnetic field H, when submitted to an input bias voltage V_{dd} of 1V. The linearity error of the reference magnetic sensor 2_{Ref} when submitted at magnetic fields up to ±47 mT is ˜1.4% (curve V_{outRef} on FIG. 9 b). On the other hand, the corrected output voltage V_{corr} of a magnetic device 10 considering the same reference magnetic sensor biased by V_{dd}=1V and a cascade sensing circuit 100 formed by three magnetic sensors 2ₙ (as sketched in FIG. 7) when the cascade sensing circuit is biased at V₀=2.4V is shown by the grey curve on FIG. 9a. The linearity error of the corrected output voltage V_{corr} is ˜0.06% (curve V_{corr} in FIG. 9b) leading to a total reduction of linearity error of about 20 times.

For this particular embodiment, in order to ensure a high linear response of the magnetic sensor device 10, the bias voltage applied to the cascade magnetic sensor circuit 100 (V₀) must be proportional to the bias voltage applied to the reference magnetic sensor (V_{dd}), as shown by Eq. 15:

$${V}_{0} = K ( {a}_{1} , {a}_{3} ) \cdot {V}_{d d} , \qquad Eq . 15 a$$

where K is the correction coefficient depending on the linear and third-order coefficients, a₁ and a₃ respectively, of the reference magnetic sensor response, as described by Eq. 2b. In particular:

$$K = k \cdot \frac{{a}_{3}}{{a}_{1}^{3}} , \qquad Eq . 15 b$$

with k being a constant. However, in a more general embodiment (b≠a) the relationship between both parameters to ensure a high linear response of the magnetic sensor device 10 would be:

$$\frac{b}{a} = K ( {a}_{1} , {a}_{3} ) \cdot \frac{{V}_{d d}}{{V}_{0}} . \qquad Eq . 15 c$$

Note that for this particular embodiment (cascade sensing circuit 10 comprising three similar magnetic sensors than the reference magnetic sensor) the correction coefficient K is only depending on on the linear and third-order coefficients, a₁ and a₃ (K=K(a₁, a₃)). For other configurations, high order coefficients (aᵢ with i>3) might be involved in order to determine the optimum correction parameters.

In a more general embodiment, the magnetic sensor device 10 can comprise a cascade sensing circuit 10 involving different magnetic sensors generating an output voltage:

$${V}_{outCascade} = {\sum }_{n = 1}^{N} {α}_{n} \cdot {V}_{outn} \qquad 15 d$$

$$with$$

$${V}_{outn} = {v}_{s \_ n} ( H ) \cdot {V}_{outn - 1} \qquad 15 e$$

where v_{s_n} (H) is the normalized output voltage of the n^{th} magnetic sensor of the cascade senor circuit, Vₒᵤₜₙ and V_{outn_1} are the output voltages of the n^{th} magnetic sensor and n^{th}−1 magnetic sensor of the magnetic sensor circuit and αₙ is a correction parameter depending on all a₁, . . . , aₙ coefficients of all n magnetic sensors 2 comprised in the magnetic sensor device 10.

From the reference output voltage V_{outRef} versus the applied magnetic field H curve of FIG. 9a, the following values can be derived: a₁˜4.24 mV/V/mT and a₃˜1.4276 mV/V/mT³. Thus, according to equation 15a, the ratio V₀/V_{dd} must be close to 2.17 for an optimal linear response of the magnetic sensor device 10 of FIG. 5, in good concordance with the obtained ratio of 2.4.

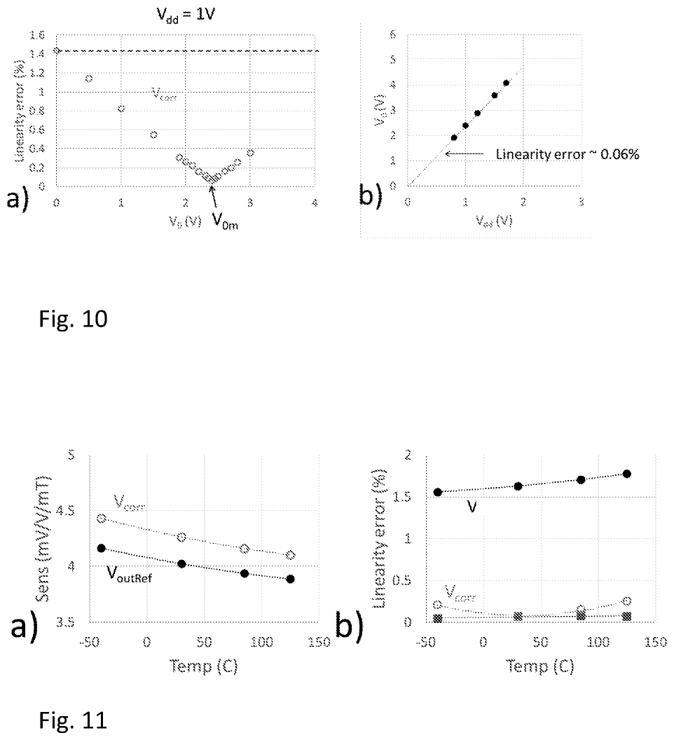

FIG. 10a shows the dependence of the linearity error of the corrected output voltage V_{corr} as a function of the input bias voltage V₀ when the input bias voltage V_{dd} equal 1V. The linearity error is minimum (˜0.06%) at V₀=V₀ₘ=2.4V and increases almost linearly with [V₀− V₀ₘ].

FIG. 10b shows the experimentally determined input bias voltage V₀ of the cascade sensing circuit 100 necessary to obtain the lowest linearity error (˜0.06%) of the corrected output voltage V_{corr} of the reference magnetic sensor 2_{Ref} when the reference magnetic sensor 2_{Ref} is biased at V_{dd}. The ratio V₀/V_{dd} is the same for the four measured points of experimentally determined input bias voltage V₀, as predicted by equation 15a.

The robustness of the linear response of the magnetic sensor device 10 of FIG. 7 as a function of temperature was evaluated. The response of the magnetic sensor device 10 for an applied magnetic field H of up to ±50 mT at −40° C., 30° C., 85° C. and 125° C. was measured.

FIGS. 11a and 11b show the sensitivity (FIG. 11a) and linearity error (FIG. 11b) of the reference magnetic sensor 2_{Ref} of the magnetic sensor device 10 of FIG. 7 as a function of temperature (black dots). The temperature coefficient of sensitivity (TCS) is equal to about −420 ppm/C and the linearity error is between 1.56%-1.78% through all the temperature range. Similarly, the sensitivity and linearity error of the temperature dependence of the corrected output voltage V_{corr} from the magnetic sensor device 10 (see FIG. 7) is also plotted (open dots, showing a similar TCS of about −460 ppm/C and a linearity error between 0.06% and 0.25%. The input bias voltage V₀ was kept constant (V₀˜2.4V) at all temperature ranges.

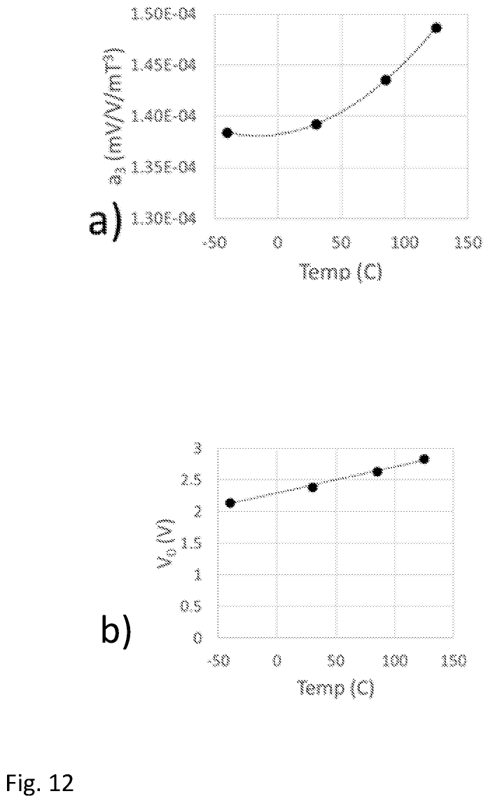

As shown in FIG. 12a, the third order coefficient a₃ is also temperature dependent. This implies that in order to fully optimize the linearity error of the magnetic sensor device 10, the input bias voltage V₀ should be varied over temperature. FIG. 12b shows a possible variation of the input bias voltage V₀ such that the linearity error is smaller than 0.08% at all temperature range (see square dots in FIG. 11b). However, reasonable linearity error (<0.3%) is obtained when keeping V₀ constant over temperature.

The linear dependence of V₀ with temperature highlights the possibility to contemplate a correction temperature such that the magnetic sensor device 10 has a low TCS, for example a TCS smaller than −100 ppm/C, a linearity error smaller than 0.1% over the whole temperature range, and a sensitivity greater than 4 mV/V/mT for an applied magnetic field H up to 50 mT.

The cascade magnetic sensor circuit 100 and the magnetic sensor device 10 can also be implemented in 2D magnetic sensors (magnetic sensors sensitive to the orientation of the external magnetic field) or also called angular magnetic sensors to linearize its sinusoidal response. Such implementation can improve the working angular range of the 2D magnetic sensor for auto-focus (AF) applications or for developing a full analog 2D linear sensor.

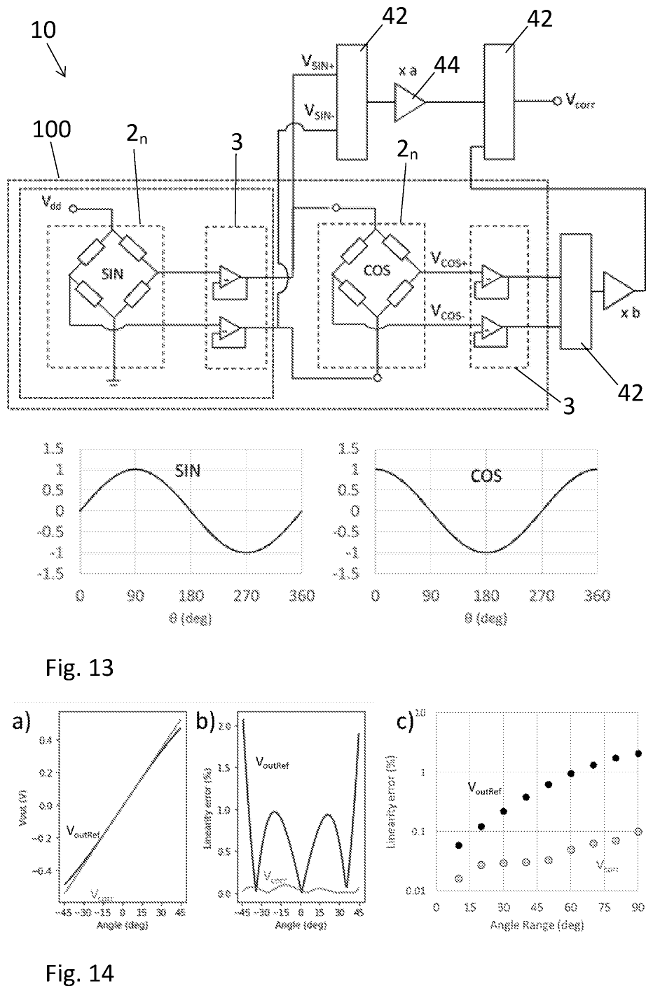

According to this embodiment, FIG. 13 illustrates a 2D magnetic sensor device 10 with a linearized response with respect to the magnetic field orientation angle θ. The magnetic sensor device 10 comprises a cascade magnetic sensor circuit 100 with two 2D full bridge magnetic sensors 2ₙ connected in cascade, where the first 2D magnetic sensor is used as a reference magnetic sensor.

At high level, the first 2D full bridge magnetic sensor 2ₙ₌₁ or 2_{Ref} follows a response with respect to the orientation θ of the external magnetic field vector H with respect to a certain predefined axis in a coordinate system. described by Eq. 16:

$${V}_{outRef} = {V}_{SIN} = {V}_{dd \_ SIN} \cdot {A}_{SIN} \cdot sin θ . \qquad Eq . 16$$

Similarly, the second 2D full bridge magnetic sensor 2n=₂ follows a response with respect to the orientation θ of the external magnetic field vector H with respect to a certain predefined axis in a coordinate system described by Eq. 17:

$${V}_{COS} = {V}_{dd \_ C O S} \cdot {A}_{COS} \cdot cos θ , \qquad Eq . 17$$

where V_{dd_SIN} and V_{dd_COS} are the bias voltage submitted to both magnetic sensors and A_{SIN} and A_{COS} are the normalized amplitude voltages of both signals. Note the normalized output voltage for both sensors are therefore:

$${v}_{s \_ SIN} = {A}_{SIN} \cdot sin θ \qquad Eq . 18 a$$

$${v}_{s \_ COS} = {A}_{COS} \cdot cos θ . \qquad Eq . 18 b$$

With this cascade configuration the output voltage of the first 2D full bridge magnetic sensor (V_{SIN}) is used as the input bias voltage of the second 2D full bridge magnetic sensor 2₂. Therefore, the same bias voltage submitted to both full bridge magnetic sensors (V_{dd}=V_{dd_SIN}=V_{dd_COS}) considering similar normalized amplitude voltages (A=A_{SIN}=A_{COS}), the cascade output voltage of this system will be (following Eq. 4a):

$${V}_{outCascade} = = {V}_{d d} \cdot {A}^{2} \cdot sin θ \cdot cos θ . \qquad Eq . 19$$

By considering Eq.16 and Eq.19 in Eq.11, the corrected output voltage of this magnetic sensor device 10 is:

$${V}_{corr} = {V}_{d d} \cdot A \cdot ( a \cdot sin θ - b \cdot A \cdot sin θ \cdot cos θ ) . \qquad Eq . 20$$

Note that for a certain angle range θ, both SIN and COS response can be described up to a third order as:

$$sin θ ∼ θ - \frac{{θ}^{3}}{6} \qquad Eq . 20 a$$

$$cos θ ∼ 1 - \frac{{θ}^{2}}{2} \qquad Eq . 20 b$$

$$or :$$

$$sin θ ∼ {a}_{1} \cdot θ - {a}_{3} \cdot {θ}^{3} \qquad Eq . 20 c$$

$$cos θ ∼ 1 - \tilde{{a}_{2}} \cdot {θ}^{2} \qquad Eq . 20 d$$

with: α₁=1, α₃=⅙ & [symbol] =½ being a₁ and a₃ the first and third order coefficient of the SIN full bridge magnetic sensor and [symbol] the second order coefficient of the COS full bridge magnetic sensor.

Therefore, by adjusting the values of parameters a and b with respect to coefficients a₁, a₃ & [symbol] of both SIN & COS full bride sensors, the corrected output voltage V_{corr} can show, up to a certain angle range, a linear dependence with respect to the orientation θ of the external magnetic field vector H.

FIG. 14a shows both the reference output voltage V_{outRef} and the corrected output voltage V_{corr} with respect to the magnetic field orientation θ between [−45°, 45° ]. For this case, a ˜1.38 and b˜0.38/A. Linearity error with respect to the magnetic field orientation θ at this angle range for both V_{outRef} and V_{corr} is shown in FIG. 14b. Note that linearity error of V_{corr} is ˜0.1% at this angular range, which is ×20 smaller than V_{outRef}. FIG. 14c, shows the impact of angle range on linearity error for both the reference 2D magnetic sensor (V_{outRef}) and the proposed magnetic sensor device 10 (V_{corr}). Typically, a 2D magnetic sensor shows a linearity error 0.1% only for angular ranges between [−10°, 10° ] and linearity error increases dramatically with angular range. On the other hand, magnetic sensor device 10 enables to obtain a similar linearity error by increasing the working angular range by about 4.5 times.

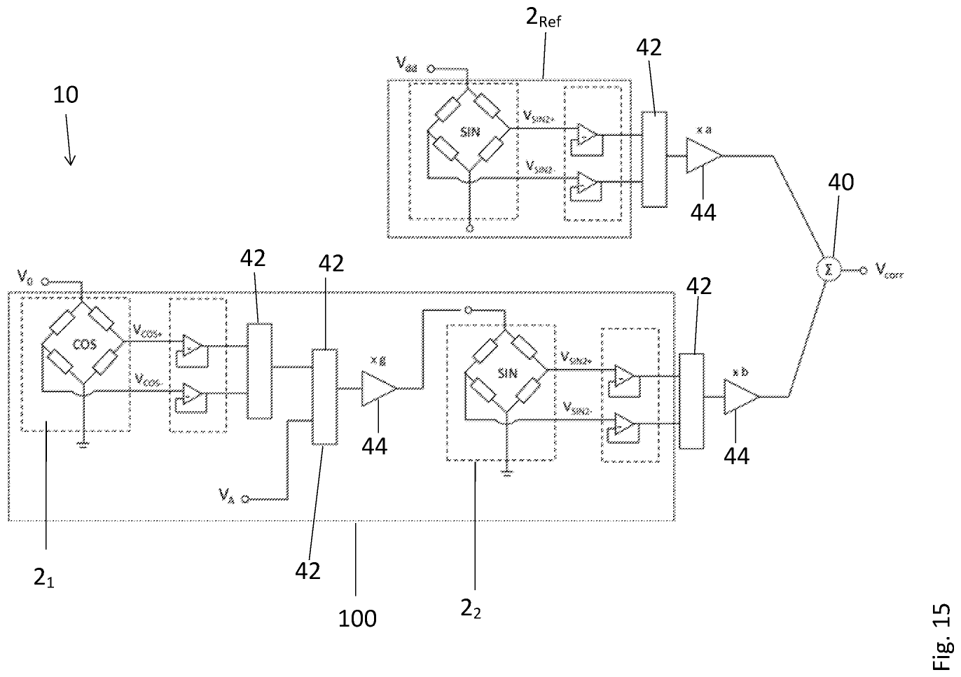

According to another embodiment, FIG. 15 illustrates an alternative 2D magnetic sensor device 10 with a linearized response with respect to the magnetic field orientation θ. In this case, however, the reference magnetic sensor 2_{Ref} is not part of the cascade magnetic sensor circuit 100 as in FIG. 14. Note, also that between two stages of the cascade magnetic sensor circuit 100 a differential amplifier 42 and an amplification 44 is used (amplification stage g). An amplification 44 can also be used after a differential amplifier 42 at the end of the cascade magnetic sensor circuit 100 (amplification stage b) and after a differential amplifier 42 of the reference magnetic sensor 2_{Ref} (amplification stage a).

Different other configurations of the 2D full bridge magnetic sensor device 10 described in FIG. 14 can be considered in order to obtain a similar improvement of the linearity error. The cascade sensor circuit 100 of FIG. 15 is configured so the output voltage Vₒᵤₜ, of the first magnetic sensors 2₁ of the cascade circuit 100 is subtracted from an additional voltage signal V_{add} and then amplified by factor g. This signal is then used as the bias voltage of the 2^{nd} magnetic sensor 2₂ V_{0_2}:

$${V}_{0 \_ 2} = ( {V}_{a d d} - {V}_{out 1} ) \cdot g , \qquad Eq . 21$$

and to generate a cascade output voltage:

$${V}_{outCascade} = ( {V}_{add} - {V}_{0} \cdot {v}_{s \_ 1} ) \cdot g \cdot {v}_{s \_ 2} , \qquad Eq . 22$$

where V₀ is the bias voltage of the first magnetic sensor of the cascade sensor circuit and v_{s_1} (H) is the normalized output voltage of the first magnetic sensor and the of the cascade sensor circuit and v_{s_2}(H) is the normalized output voltage of the second magnetic sensor and the of the cascade sensor circuit.

Considering the SIN and COS response of the first and second magnetic sensor of the cascade sensor circuit 100 of FIG. 15, The corrected output voltage of this magnetic sensor device 10 can then be written as:

$${V}_{corr} = a \cdot {V}_{dd} \cdot A \cdot sin θ + b \cdot ( {V}_{add} - {V}_{0} \cdot A \cdot cos θ ) \cdot g \cdot A \cdot sin θ , \qquad Eq . 23$$

where V_{dd} is the bias voltage of the reference magnetic sensor, V_{add} is the additional bias voltage used at the output of the first magnetic sensor of the cascade sensor circuit and g is an amplification factor.

By adjusting the values of parameters a, b with respect to coefficients a₁, a₃ & [symbol] of both SIN & COS full bride sensors, the amplification factor g as well as input bias voltages V₀ and V_{A} as: a˜1, V₀˜V_{dd}, V_{add}˜A·V_{dd} and b·g˜0.38/(A) the corrected output voltage V_{corr} can show, up to a certain angle range, a similar linear dependence with respect to the orientation θ of the external magnetic field vector H than the previous embodiment shown in FIG. 14.

Generally, we can describe this embodiment as a magnetic sensor device 10 wherein the corrected output voltage (V_{corr}) of the magnetic sensor device 10 is determine by Eq.11 and wherein the cascade sensor circuit 100 is configured to generate an output voltage (V_{outCascade}):

$${V}_{outCascade} = {V}_{0} \cdot {\prod }_{n = 1}^{N} {V}_{outStage \_ n} \qquad Eq . 24 a$$

$${V}_{outStage \_ n} = {g}_{n} \cdot [ {V}_{outStage \_ n - 1} \cdot {v}_{{s}_{n}} ( H ) + {V}_{add \_ n} ] \qquad Eq . 24 b$$

where V₀ is the bias voltage of the cascade sensor circuit 100, V_{add_n} is the additional bias voltage added to the output voltage of the n^{th} magnetic sensor, gₙ is the amplification factor at the n^{th} stage of the cascade sensor circuit and V_{outStage_n} is the output voltage at the n^{th} stage of the cascade sensor circuit 100 and v_{s_n}(H) is the normalized output voltage of the n^{th} magnetic sensor of the cascade sensor circuit. Note that both gₙ and V_{add_n} can be dependent on magnetic sensors' coefficients a₁, . . . , aₙ.

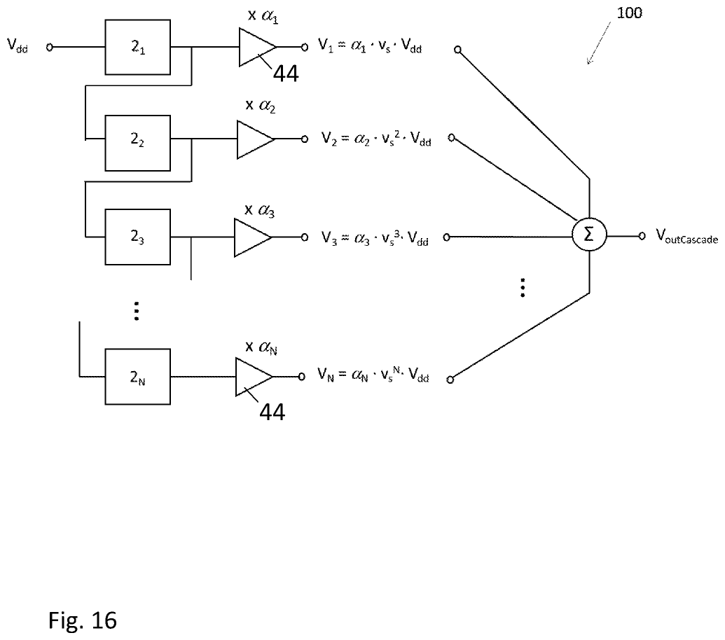

Finally, the cascade sensor circuit 100 can be configured not only to correct the high order component of a reference output voltage V_{outRef} but also to generate any desired polynomial output voltage response that might be useful for other purposes as sketched in FIG. 16.

For example, the cascade sensor circuit 100 can comprise an adder circuit comprising N magnetic sensors 2ₙ, wherein N equal to or greater than 2, and include a first magnetic sensor 2₁ and at least another magnetic sensor 2ₙ electrically connected in cascade with each other. The first magnetic sensor 2₁ can be configured to generate a first output voltage Vₒᵤₜ₁ dependent on the external magnetic field vector H when submitted to an input bias voltage V_{dd}. The first output voltage Vₒᵤₜ₁ of the first magnetic sensor 2₁ can be used as a bias voltage of the next magnetic sensor 2₂. The N-1 output voltage V_{outN-1} of the N-1 magnetic sensor 2_{N-1} can be used to bias voltage the N magnetic sensor 2_{N}. In other words, the output voltage Vₒᵤₜₙ of the n^{th} magnetic sensor 2ₙ of the cascade sensor circuit 100 is divided to also supply the bias voltage of the n^{th}+1 magnetic sensor 2ₙ₊₁ of the cascade sensor circuit 100. The output of each magnetic sensor 2ₙ is split so one part is used to biased the next magnetic sensor will the other part is amplified by an amplification coefficient an. The cascade sensor circuit 100 can further comprise and a plurality of N amplifiers 44 wherein N equal to or greater than 2. The n^{th} amplifier 44 with an amplification coefficient an has an input terminal receiving the output voltage of the n^{th} magnetic sensor 2ₙ of the cascade sensor circuit 100. The adder circuit enables the sum of each output voltage signal Vₙ from the output terminal of the each of the plurality of amplifiers 44. Therefore, the output voltage signal Vₙ at each stage n will be:

$${V}_{n} = {α}_{n} \cdot {V}_{outn} = {α}_{n} \cdot {V}_{dd} \cdot {\prod }_{j = 1}^{n} {v}_{s \_ j} . \qquad Eq . 25$$

wherein V_{dd} is the bias voltage of the first magnetic sensor of the cascade sensor circuit, Vₒᵤₜₙ is the output voltage of the n^{th} magnetic sensor of the cascade sensor circuit, and v_{s_j}(H) is the normalized output voltage of each j^{th} magnetic sensor of the cascade sensor circuit comprised between the first magnetic sensor 2₁ and the n^{th} magnetic sensor 2ₙ.

The cascade sensor circuit has then an adder circuit enabling to sum the output voltage of each n^{th} stage and therefore it is configured to generate an output voltage V_{outCascade} determined by:

$${V}_{outCascade} = {\sum }_{n = 1}^{N} {V}_{n} = {\sum }_{n = 1}^{N} {α}_{n} \cdot {V}_{outn} = {V}_{dd} \cdot {\sum }_{n = 1}^{N} {α}_{n} \cdot {\prod }_{j = 1}^{n} {v}_{s \_ j} , \qquad Eq . 26$$

where Vₒᵤₜₙ is the output voltage of the n^{th} magnetic field sensor of the cascade sensor circuit and αₙ is an amplification coefficient independent of the external magnetic field vector H dependent on all a₁, . . . , aₙ coefficients of all n magnetic sensors 2 involved at the output voltage of the n^{th}magnetic sensor of the cascade sensor circuit 100 and being, at least one of the amplification coefficients αₙ being non zero.

### REFERENCE NUMBERS AND SYMBOLS

10 magnetic sensor device
100 cascade sensing circuit
2 magnetic sensor
2₁ first magnetic sensor
2ₙ n^{th} magnetic sensor
2_{R} reference magnetic sensor
20 magnetic sensing element
3 amplifier buffer
40 summing circuit
42 differential amplifier
44 amplification
θ magnetic field orientation angle
H external magnetic field vector
N number of magnetic sensors
V₀ input bias voltage
V_{corr} corrected output voltage
V_{dd} input bias voltage, input
Vₒᵤₜ output voltage
Vₒᵤₜ₁ first output voltage
Vₒᵤₜₙ output voltage
V_{outRef} reference output voltage
V_{outCascade} cascade output voltage
V_{out1(H)} normalized output voltage

1. A magnetic sensor device for sensing an external magnetic field vector (H) comprising a cascade magnetic sensor circuit comprising N magnetic sensors (2ₙ), each magnetic sensors (2ₙ) generating an output voltage (Vₒᵤₜₙ), wherein N equal to or greater than 2, wherein the magnetic sensors (2ₙ) are electrically connected in cascade with each other;
wherein the output voltage (Vₒᵤₜₙ) of the n^{th} magnetic sensors (2ₙ) is proportional to an input bias voltage (V_{0_n}) of the n^{th} magnetic sensor (2ₙ) and to a normalized output voltage (v_{s_n}(H)) of the n^{th} magnetic sensor (2ₙ) depending on the external magnetic field vector (H):
$${V}_{o u t n} = {v}_{s \_ n} ( H ) \cdot {V}_{0 \_ n}$$
wherein the output voltage (Vₒᵤₜₙ) of one of the n^{th} magnetic sensors (2ₙ) supplies the input bias voltage (V_{0_n+1}) of the (n+1)^{th} magnetic sensor (2ₙ₊₁);
characterized in that the magnetic sensor device (10) further comprises at least one reference magnetic field sensor (2_{Ref});
wherein a corrected output voltage (V_{corr}) of the magnetic sensor device is determined by:
$${V}_{c o r r} = a \cdot {V}_{outRef} + b \cdot {V}_{o u t Cascade}$$
where a and b are correction parameters independent of the external magnetic field vector (H), V_{outRef} is a reference output voltage generated by at least one reference magnetic sensor (2_{Ref}), the corrected output voltage (V_{corr}) having improved linearity compared to the reference output voltage (V_{outRef}), and V_{outCascade} is the cascade output voltage of the cascade magnetic sensing circuit.

2. The magnetic sensor device according to claim 1,
wherein the cascade sensor circuit is configured to generate an output voltage (V_{outCascade}):
$${V}_{outCascade} = {V}_{0} \cdot {\prod }_{n = 1}^{N} {v}_{{s}_{n}} ( H ) ,$$
where v_{s_n} is the normalized output voltage of the n^{th} magnetic sensor of the cascade magnetic sensor circuit and V₀ is the input bias voltage of the first magnetic sensor of the cascade magnetic sensor circuit.

3. The magnetic sensor device according to claim 1, comprising a first magnetic sensor (2₁) cascade connected to at least another magnetic sensor (2ₙ);
the normalized output voltage (v_{s_n} (H)) of each magnetic sensor (2ₙ) having a substantially identical dependence on the external magnetic field vector (H); and
wherein the cascade magnetic sensor circuit generates an output voltage (V_{outCascade}) that is proportional to a degree N with respect to the normalized output voltage (v_{s_1} (H)) of the first magnetic sensor (2₁) and to the input bias voltage (V₀) inputted to the first magnetic sensor (vₒᵤₜ₁) of the cascade sensor circuit:
$${V}_{outCascade} = {V}_{0} \cdot {v}_{s \_ 1}^{N} .$$

4. The magnetic sensor device according to claim 2, comprising an amplification stage (gₙ) at the output of at least 1 of the N magnetic sensors of the cascade circuit, wherein the cascade sensor circuit is configured to generate an output voltage (V_{outCascade}):
$${V}_{outCascade} = {V}_{0} \cdot {\prod }_{n = 1}^{N} {g}_{n} \cdot {v}_{{s}_{n}} ( H ) .$$

5. The magnetic sensor device according to claim 4, wherein an additional positive or negative voltage signal (V_{add_n}) is added to the output voltage Vₒᵤₜₙ of at least one of the magnetic sensors (2ₙ) of the cascade circuit before the amplification stage (gₙ) so the output voltage of the n^{th} stage of the cascade sensor circuit is:
$${V}_{outStage \_ n} = {g}_{n} \cdot [ {V}_{{outStage}_{n} - 1} \cdot {v}_{{s}_{n}} ( H ) + {V}_{{add}_{n}} ] ,$$
wherein the cascade sensor circuit is configured to generate an output Voltage (V_{outCascade}):
$${V}_{outCascade} = {V}_{0} \cdot {\prod }_{n = 1}^{N} {V}_{outStage \_ n} .$$

6. The magnetic sensor device according to claim 1,
wherein all magnetic sensors comprise four magnetic sensing elements arranged in a full-bridge circuit.

7. The magnetic sensor device according to claim 6,
wherein the magnetic sensing element comprises at least one magnetoresistive element, such as a magnetic tunnel junction.

8. The magnetic sensor device according to claim 1, wherein the cascade sensor circuit is configured to generate an output voltage (V_{outCascade}) determined by:
$${V}_{outCascade} = {\sum }_{n = 1}^{N} {α}_{n = 1} \cdot {V}_{o u t n} .$$
where the αₙ is an amplification coefficient independent of the external magnetic field vector (H) and being non zero, and Vₒᵤₜₙ is the output voltage of the n^{th} magnetic sensor (2ₙ) of the cascade sensor circuit.

9. The magnetic sensor device according to claim 8,
wherein the cascade sensor circuit comprises an adder circuit and a plurality of amplifiers;
wherein the n^{th} amplifier with an amplification coefficient (aₙ) has aₙ input terminal receiving the output voltage of the n^{th} magnetic sensor (2ₙ) of the cascade sensor circuit;
wherein the output voltage (Vₒᵤₜₙ) of the n^{th} magnetic sensor (2ₙ) of the cascade sensor circuit is divided to also supply the bias voltage of the nₜₕ+1 magnetic sensor (2ₙ₊₁) of the cascade sensor circuit; and wherein the adder circuit is configured to sum each output voltage signal (Vₙ) from the output terminal of the each of the plurality of amplifiers.

10. The magnetic sensor device according to claim 1, comprising a voltage buffer at the output of each magnetic sensor of the cascade sensor circuit.

11. The magnetic sensor device according to claim 1,
wherein the cascade output voltage (V_{outCascade}) of the cascade magnetic sensing circuit is electrically connected to the reference output voltage (V_{outRef}) of the reference magnetic sensor (2_{Ref}) via a summing circuit configured to sum the cascade output voltage (V_{outCascade}) to the reference output voltage (V_{outRef}); and
wherein a corrected output voltage (V_{corr}) of the magnetic sensor device is determined by:
$${V}_{c o r r} = α \cdot {V}_{outRef} + b \cdot {V}_{outCascade} ;$$
wherein the magnetic sensor device further comprises an amplifier after the reference magnetic sensor (2_{Ref}) and an amplifier after the cascade sensing circuit.

12. The magnetic sensor device according to claim 11, wherein the cascade output voltage (V_{outCascade}) of the cascade magnetic sensing circuit is electrically connected to the reference output voltage (V_{outRef}) of the reference magnetic sensor (2_{Ref}) via a differential amplifier circuit configured to subtract the cascade output voltage (V_{outCascade}) to the reference output voltage (V_{outRef}).

13. The magnetic sensor device according to claim 1,
wherein the reference output voltage (V_{outRef}) is generated by least one of the magnetic sensors of the cascade magnetic sensing circuit.

14. The magnetic sensor device according to claim 1,
wherein the reference magnetic sensor (2_{Ref}) is an external magnetic sensor element from the cascade magnetic circuit.

15. The magnetic sensor device according to claim 1,
wherein the reference magnetic sensor (2_{Ref}) comprises four magnetic sensing elements arranged in a full-bridge circuit.

16. The magnetic sensor device according to claim 1,
comprising a voltage buffer at the output of each magnetic sensor of the magnetic sensor device.
